(19) United States
(12) Patent Application Publication
(10) Pub. No.: US 2011/0308608 A1
(43) Pub. Date: Dec. 22, 2011

(54) SOLAR CELL AND METHOD FOR MANUFACTURING THE SAME

(76) Inventors: Seunghwan Shim, Seoul (KR); Jinah Kim, Seoul (KR); Jeongbeom Nam, Seoul (KR); Indo Chung, Seoul (KR); Juhong Yang, Seoul (KR); Ilhyoung Jung, Seoul (KR); Hyungjin Kwon, Seoul (KR)

(21) Appl. No.: 13/155,704

(22) Filed: Jun. 8, 2011

(30) Foreign Application Priority Data
Jun. 18, 2010 (KR) 10-2010-0058207

(51) Int. Cl. H01L 31/0232; H01L 31/0368; H01L 31/18

(52) U.S. Cl. 136/258; 438/72; 136/259; 257/E31.128

(57) ABSTRACT

A solar includes a substrate of a first conductive type, an emitter region of a second conductive type opposite to the first conductive type and forming a p-n junction with the substrate, a first anti-reflection layer positioned on the emitter region, a first electrode connected to the emitter region, a second anti-reflection layer positioned on the first anti-reflection layer and the first electrode, and a second electrode connected to the substrate.

### CROSS-REFERENCE TO RELATED APPLICATION

This application claims priority to and the benefit of Korean Patent Application No. 10-2010-0058207 filed in the Korean Intellectual Property Office on Jun. 18, 2010, the entire contents of which are incorporated herein by reference.

### BACKGROUND OF THE INVENTION

(a) Field of the Invention

Embodiments of the invention relate to a solar cell and a method for manufacturing the same.

(b) Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A solar cell generally includes semiconductor parts that have different conductive types, such as a p-type and an n-type, and form a p-n junction, and electrodes respectively connected to the semiconductor parts of the different conductive types.

When light is incident on the solar cell, electron-hole pairs are generated in the semiconductor parts. The electrons move to the n-type semiconductor part and the holes move to the p-type semiconductor part, and then the electrons and holes are collected by the electrodes connected to the n-type semiconductor part and the p-type semiconductor part, respectively. The electrodes are connected to each other using electric wires to thereby obtain electric power.

### SUMMARY OF THE INVENTION

According to an aspect of the present invention, a solar cell may include a substrate of a first conductive type, an emitter region of a second conductive type opposite to the first conductive type and forming a p-n junction with the substrate, a first anti-reflection layer positioned on the emitter region, a first electrode connected to the emitter region, a second anti-reflection layer positioned on the first anti-reflection layer and the first electrode, and a second electrode connected to the substrate.

The solar cell may further include a bus bar connected to the emitter region and the first electrode.

The second anti-reflection layer may be not positioned on the bus bar.

A level of an upper surface of the second anti-reflection layer positioned on the first anti-reflection layer may be lower than a level of an upper surface of the bus bar.

A level of an upper surface of the second anti-reflection layer positioned on the first anti-reflection layer may be higher than a level of an upper surface of the bus bar.

The second anti-reflection layer may include a first portion positioned on the first anti-reflection layer and a second portion positioned on the first electrode, and levels of upper surfaces of the first and second portion may be substantially equal to each other.

The second anti-reflection layer may include a first portion positioned on the first anti-reflection layer and a second portion positioned on the first electrode, and levels of upper surfaces of the first and second portion may be different from each other.

The level of the upper surface of the first portion of the second anti-reflection layer may be lower than the level of the upper surface of the second portion of the second anti-reflection layer.

The first anti-reflection layer may be positioned only on portions of the emitter regions, on which the first electrode and the bus bar are not positioned, so that the first and second anti-reflection layers are positioned on the emitter region as a double-layered structure and the second anti-reflection layer is positioned on the first electrode as a single-layered structure.

A refractive index of the first anti-reflection layer may be greater than a refractive index of the second anti-reflection layer.

The refractive index of the first anti-reflection layer may be about 2.1 to 2.4 and the refractive index of the second anti-reflection layer may be about 1.6 to 2.0.

The first and second anti-reflection layers may be made of a same material.

The first and second anti-reflection layers may be made of silicon oxide or silicon nitride.

The first and second anti-reflection layers may be made of a different material from each other.

The second anti-reflection layer may be made of at least one of an oxide, a non-oxide, and a polymer-based material.

The first and second anti-reflection layers may be made of silicon oxide or silicon nitride.

The second anti-reflection layer may have a thickness of about 1 μm to 600 μm.

The first anti-reflection layer may have a thickness less than a thickness of the second anti-reflection layer.

The first anti-reflection layer may have a thickness of about 30 nm to 100 nm.

The solar cell may further include a field region positioned connected to the second electrode.

The substrate may be a polycrystalline silicon substrate of a purity level of 5 N or less.

The substrate may be a polycrystalline silicon substrate of a purity level of 2 N to 5 N.

The substrate may be a metallurgical grade silicon substrate.

The substrate may include aluminum (Al) in an amount of 0.01 ppmw to 0.8 ppmw.

The substrate may include iron (Fe) in an amount of 0.01 ppmw to 0.8 ppmw.

According to another aspect of the present invention, a method for manufacturing a solar cell may include forming an emitter region on a front surface of the substrate to form a p-n junction with the substrate, forming a first anti-reflection layer on the emitter region, locally forming a front electrode pattern on the first anti-reflection layer, forming a back electrode pattern on a back surface of the substrate, forming a second anti-reflection layer on the first anti-reflection layer and the front electrode pattern, and forming a front electrode using the front electrode pattern that penetrates through the first anti-reflection layer and connects to the emitter region, and a back electrode using the back electrode pattern that connects to the substrate.

The front electrode pattern may include a first portion and a second portion, and the front electrode comprises a finger electrode and a bus bar connected to the finger electrode, and the first portion forms the finger electrode and the second may form the bus bar.

The second anti-reflection layer may be positioned on the first portion, so that the second anti-reflection layer may be positioned not on the bus bar but on the finger electrode.

According to further another aspect of the present invention, a method for manufacturing a solar cell may include forming an emitter region on a front surface of the substrate to form a p-n junction with a substrate, forming a first anti-reflection layer on the emitter region, locally forming a front electrode pattern on the first anti-reflection layer, forming a back electrode pattern on a back surface of the substrate, forming a front electrode using the front electrode pattern that penetrates through the first anti-reflection layer and connects to the emitter region, and a back electrode using the back electrode pattern that connects to the substrate, and forming a second anti-reflection layer on the first anti-reflection layer and a portion of the front electrode.

The front electrode may include a finger electrode and a bus bar connected to the finger electrode.

The portion of the front electrode on which the second anti-reflection layer may be formed is the finger electrode.

The first anti-reflection layer may be formed by a plasma enhanced chemical vapor deposition method.

The second anti-reflection layer may be formed by a printing method.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a partial perspective view of a solar cell according to an example embodiment of the invention;

FIG. 2 is a cross-sectional view taken along line II-II of FIG. 1;

FIG. 3 depicts a graph illustrating reflectivity according to variation of a wavelength of light according to an example embodiment of the present invention and a graph illustrating reflectivity according to variation of a wavelength of light according to a comparative example;

FIGS. 4A to 4F are cross-sectional views sequentially illustrating a method for manufacturing a solar cell according to an example embodiment of the present invention;

FIGS. 5A and 5B are cross-sectional views illustrating portions of another method for manufacturing a solar cell according to an example embodiment of the present invention; and

FIGS. 6 and 7 are partial perspective views of solar cells according to another example embodiment of the invention respectively.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Reference will now be made in detail to embodiments of the invention, examples of which are illustrated in the accompanying drawings.

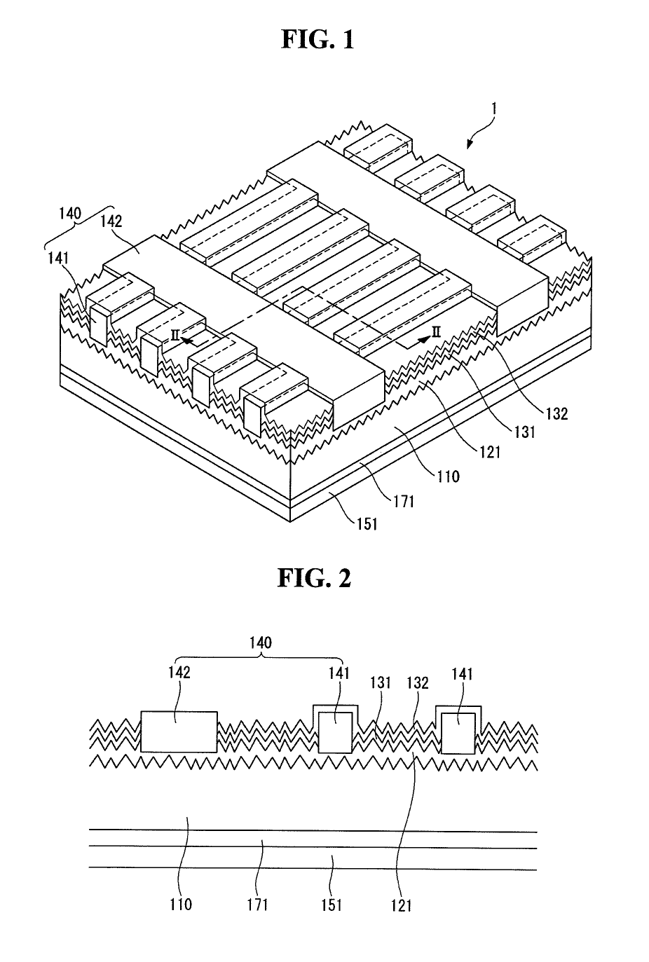

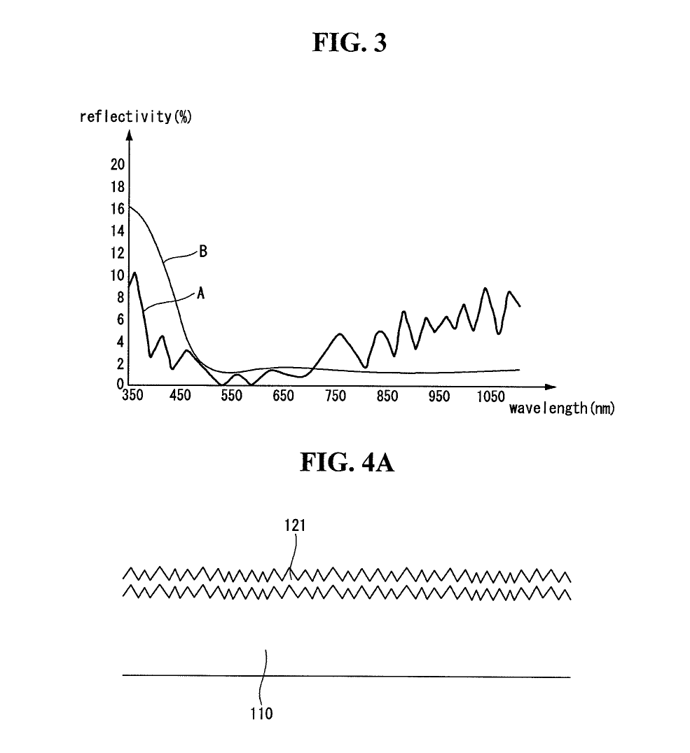

A solar cell according to an embodiment of the invention is described in detail with reference to FIGS. 1 and 2.

FIG. 1 is a partial perspective view of a solar cell according to an embodiment of the invention. FIG. 2 is a cross-sectional view taken along line II-II of FIG. 1.

As shown in FIGS. 1 and 2, a solar cell 1 according to an example embodiment of the invention includes a substrate 110, an emitter region 121 positioned at an incident surface (hereinafter, referred to as “a front surface”) of the substrate 110 on which light is incident, a first anti-reflection layer 131 positioned on the emitter region 121, a front electrode 140 connected to the emitter region 121 and including a plurality of finger electrodes 141 and a plurality of front bus bars 142, a second anti-reflection layer 132 positioned on the first anti-reflection layer 131 and the plurality of finger electrodes 141, a back electrode 151 positioned on a surface (hereinafter, referred to as “a back surface”), opposite the front surface of the substrate 110, on which light is not incident, and a back surface field region (or a field region) 171 positioned into (at) the substrate 110.

The substrate 110 is a semiconductor substrate, and may be formed of a first conductive type silicon, for example, p-type, though not required. Silicon used in the substrate 110 is polycrystalline silicon but may be single crystal silicon in other embodiments of the invention. When the substrate 110 is of a p-type, the substrate 110 may contain impurities of a group III element such as boron (B), gallium (Ga), and indium (In). Alternatively, the substrate 110 may be of an n-type, and/or be formed of other semiconductor materials other than silicon. When the substrate 110 is of the n-type, the substrate 110 may contain impurities of a group V element such as phosphor (P), arsenic (As), and antimony (Sb).

However, in an alternative example, the substrate 110 may be a polycrystalline silicon substrate with a silicon purity level of less than 5 N. More specifically, the substrate 110 may be a polycrystalline silicon substrate with a silicon purity level of 2 N to 5 N.

In an alternative example, the substrate 110 may also be a metallurgical grade silicon substrate. In addition, the substrate 110 may include metallic impurities. In embodiments of the invention, reference to metallurgical grade silicon refers to purity of the silicon that may be about 98.0% to 99.9% pure, and which is less than solar grade silicon.

By using the substrate 110 of the above alternative examples, a manufacturing cost of the substrate 110 may be reduced and accordingly, a manufacturing cost of the solar cell may be reduced.

The purity level of 5 N of the substrate 110 refers to the silicon content of the substrate 110 being approximately 99.999% (the number of FIG. 9 is five, 99.999˜99.9998%, for example). Put differently, the purity level of 5 N refers to the substrate 110 having a silicon content of approximately 99.999% grade. If the purity level of the substrate 110 is 7 N, it refers to the silicon content being of approximately 99.99999% grade.

The metallic impurities may be at least one of aluminum (Al) and iron (Fe). The content of the metallic impurities contained in the substrate 110 is 0.001 ppmw to 1.0 ppmw, and in an embodiment of the invention, the content (or amount) of aluminum (Al) contained in the substrate 110 is 0.01 ppmw to 0.8 ppmw, and the content (or amount) of iron (Fe) contained in the substrate 110 is 0.01 ppmw to 1 ppmw.

The emitter region 121 is a region obtained by doping the substrate 110 with impurities of a second conductive type (for example, n-type) opposite the first conductive type (for example, p-type) of the substrate 110, so as to be an n-type semiconductor, for example. The emitter region 121 is positioned at the incident surface, that is, the front surface, of the substrate 110 on which light is incident. The emitter region 121 of the second conductive type forms a p-n junction along with a first conductive type region of the substrate 110.

The emitter region 121, that is, the front surface of the substrate 110, is textured to form a textured surface corresponding to an uneven surface with a plurality of jagged portions or having uneven characteristics. By the textured surface, an area of the incident surface of the substrate 110 is increased and reflectivity of light in the upper surface (incident surface) of the substrate 110 is reduced, and accordingly, absorption of light into the solar cell 1 is increased.

By a built-in potential difference resulting from the p-n junction between the substrate 110 and the emitter region 121, electrons and holes produced by light incident on the substrate 110 move to the n-type semiconductor and the p-type semiconductor, respectively. Thus, when the substrate 110 is of the p-type and the emitter region 121 is of the n-type, the holes move to the back surface of the substrate 110 and the electrons move to the emitter region 121.

Because the emitter region 121 forms the p-n junction along with the substrate 110 (i.e., a first conductive portion of the substrate 110), the emitter region 121 may be of the p-type when the substrate 110 is of the n-type unlike the example embodiment described above. In this instance, the electrons move to the back surface of the substrate 110 and the holes move to the emitter region 121.

Returning to the example embodiment of the invention, when the emitter region 121 is of the n-type, the emitter region 121 may be formed by doping the substrate 110 with impurities of a group V element. On the contrary, when the emitter region 121 is of the p-type, the emitter region 121 may be formed by doping the substrate 110 with impurities of a group III element.

The first anti-reflection layer 131 positioned on the emitter region 121 has a refractive index of about 2.1 to 2.4 and is formed of hydrogenated silicon nitride (SiNx:H) or hydrogenated silicon oxide (SiOx:H). However, the first anti-reflection layer 131 may be other materials with the refractive index of about 2.1 to 2.4.

In the example embodiment of the invention, the first anti-reflection layer 131 has a thickness of about 30 nm to 100 nm.

The first anti-reflection layer 131 reduces reflectivity of light incident on the solar cell 1 and increases selectivity of a particular wavelength region, thereby improving the efficiency of the solar cell 1.

In addition, the first anti-reflection layer 131 performs a passivation function that converts a defect, for example, dangling bonds existing at and around the surface of the substrate 110 into stable bonds to thereby prevent or reduce a recombination and/or a disappearance of carriers (i.e., electrons and/or holes) moving to the surface of the substrate 110.

Because silicon nitride (SiNx) has a characteristic of a positive fixed charge, when the first anti-reflection layer 131 is formed of silicon nitride (SiNx), a movement of holes toward the front surface of the substrate 110 of the p-type is prevented or reduced, while the electrons is attracted to the emitter region 121 positioned on the front surface of the substrate 110. Thereby, charge transfer efficiency from the substrate 110 to the emitter region 121 or to the back surface of the substrate 110 is improved.

When the thickness of the first anti-reflection layer 131 is less than the lowest limit (about 30 nm), an anti-reflection function and the passivation function of the first anti-reflection layer 131 decreases. When the thickness of the first anti-reflection layer 131 is greater than the greatest limit (about 100 nm), an amount of light absorbed in the first anti-reflection layer 131 increases and the thickness of the first anti-reflection layer 131 unnecessarily increase to increase the manufacturing cost and time.

The plurality of finger electrodes 141 of the front electrode 140 are electrically and physically connected to the emitter region 121 and extend substantially parallel to one another in a fixed direction at a distance therebetween. The plurality of finger electrodes 141 collect charges (e.g., electrons) moving to the emitter region 121.

The plurality of front bus bars 142 of the front electrode 140 are electrically and physically connected to the emitter region 121 and extend substantially parallel to one another in a direction crossing an extending direction of the finger electrodes 141.

The finger electrodes 141 and the front bus bars 142 are placed on the same level layer (or are coplanar). The finger electrodes 141 and the front bus bars 142 are electrically and physically connected to one another at crossings of the finger electrodes 141 and the front bus bars 142.

As shown in FIG. 1, the plurality of finger electrodes 141 have a stripe shape extending in a transverse or longitudinal direction, and the plurality of front bus bars 142 have a stripe shape extending in a longitudinal or transverse direction. Thus, the front electrode 140 has a lattice shape on the front surface of the substrate 110.

The plurality of front bus bars 142 collect not only charges transferred from portions of the emitter region 121 contacting the plurality of front bus bars 142 but also the charges collected by the plurality of finger electrodes 141.

Because the plurality of front bus bars 142 collect the charges collected by the plurality of finger electrodes 141 and move the charges to a desired location, a width of each of the plurality of front bus bars 142 is greater than a width of each of the plurality of finger electrodes 141.

The front electrode 140 having the plurality of finger electrodes 141 and the plurality of front bus bars 142 contains a conductive material such as silver (Ag). However, the conductive material may contain at least one selected from a group of nickel (Ni), copper (Cu), aluminum (Al), tin (Sn), zinc (Zn), indium (In), titanium (Ti), gold (Au), and a combination thereof or other conductive materials different from the above.

In FIG. 1, the number of finger electrodes 141 and the number of front bus bars 142 are only examples, and thereby, the number of front electrodes 141 and the number of front bus bars 142 may vary.

As described above, since the second anti-reflection layer 132 is positioned on the first anti-reflection layer 131 and the plurality of finger electrodes 141, a formation position of the first anti-reflection layer 131 is different from that of the second anti-reflection layer 132. That is, the first anti-reflection layer 131 is positioned on portions of the emitter region 121 positioned at the front surface of the substrate 110, on which the plurality of finger electrodes 141 and the plurality of front bus bars 142 are not positioned, and the second anti-reflection layer 132 is positioned on the first anti-reflection layer 131 and the plurality of finger electrodes 141. Thereby, an anti-reflection film positioned on the emitter region 121 has two layers (that is, the first and second anti-reflection layers 131 and 132) and the anti-reflection film positioned on each of the finger electrodes 141 has one layer (that is, the second anti-reflection layer 132). Further, the anti-reflection layer is not positioned on the front bus bars 142.

Thereby, the second anti-reflection layer 132 includes portions exposing the plurality of front bus bars 142.

The second anti-reflection layer 132 has a refractive index less than that of the first anti-reflection layer 131. For example, the second anti-reflection layer 132 may have the refractive index of about 1.6 to 2.0.

The second anti-reflection layer 132 may be formed of the same material as the first anti-reflection layer 131. Thereby, the second anti-reflection layer 132 may be formed by hydrogenated silicon oxide (SiOx:H) or hydrogenated silicon nitride (SiNx:H). The second anti-reflection layer 132 performs the passivation function along with the first anti-reflection layer 131.

However, in an alternative example, the second anti-reflection layer 132 may be formed of a material different from the first anti-reflection layer 131. For example, the second anti-reflection layer 132 may be formed using oxide materials such as Al₂O₃, non-oxide materials of MgF, or polymer-based materials. When the second anti-reflection layer 132 is made of Al₂O₃, the second anti-reflection layer 132 may perform the passivation function using aluminum (Al).

The second anti-reflection layer 132 decreases a reflection amount of light incident on the solar cell 1, and forms a double-layered anti-reflection structure along with the first anti-reflection layer 131 underlying the second anti-reflection layer 132 to further improve an effect for preventing reflection (referred to as ‘an reflection prevention effect’) of light incident from an external source.

That is, since the first and second anti-reflection layers 131 and 132 have the refractive indices between that of air (a refractive index: 1) and the substrate 110 (a refractive index about 3.4), and the refractive index of the first anti-reflection layer 131 is greater than that of the second anti-reflection layer 132, the refractive index thereof sequentially vary in going from air to the substrate 110. Thereby, the reflection prevention effect is further improved.

Furthermore, since portions of the second anti-reflection layer 132 are positioned on the plurality of finger electrodes 141, the plurality of finger electrodes 141 are protected by the second anti-reflection layer 132.

Thereby, the permeation of moisture or impurities from the outside to the finger electrodes 141 are blocked by the second anti-reflection layer 132, and thereby corrosion or characteristics change of the finger electrodes 141 is prevented or decreased. Thereby, a lifetime of the solar cell 1 is elongated.

Since the second anti-reflection layer 132 protects the plurality of finger electrodes 141, a thickness of the second anti-reflection layer 132 is thicker than that of the first anti-reflection layer 131. The thickness of the second anti-reflection layer 132 is changed by a reflection property of a material used therefor, but the second anti-reflection layer 132 may have the thickness of about 1 μm to several hundreds of micrometers(μm) (e.g., 300 μm to 800 μm or a value in between thereof). In an example embodiment of the invention, the second anti-reflection layer 132 may have the thickness of about 1 μm to 600 μm.

Thus, since the double-layered anti-reflection film of the first and second anti-reflection layers 131 and 132 is positioned on the emitter region 121 and the single-layered anti-reflection film of second anti-reflection layer 132 is positioned on the finger electrodes 141, the total thickness of the anti-reflection film on the emitter region 121 is more than that of the anti-reflection film on each finger electrode 141.

When the thickness of the second anti-reflection layer 132 is less than the lowest limit (about 1 μm), the second anti-reflection layer 132 does not entirely cover the plurality of finger electrodes 141, and thereby portions of the finger electrodes 141 are exposed. Accordingly, the function of the second anti-reflection layer 132 which protects the finger electrodes 141 is not normally performed. When the thickness of the second anti-reflection layer 132 is greater than the greatest limit (several hundreds of micrometers), an amount of light absorbed and dissipated in the second anti-reflection layer 132 increases and waste of a material (or use of material greater than what is needed) for the second anti-reflection layer 132 increases.

In embodiments of the invention, a thickness of the second anti-reflection layer 132 on the first anti-reflection layer 131 and a thickness of the second anti-reflection layer 132 on the finger electrodes 141 may be the same.

The plurality of front bus bars 142, on which the second anti-reflection layer 132 is not positioned and are therefore exposed, are connected to a conductive tape etc., connected to an external device and output the charges collected by the front bus bars 142 to the external device through the conductive tape, etc.

As shown in FIGS. 1 and 2, in the example, surface levels (that is, levels of upper surfaces) of each finger electrode 141 and each front bus bar 142, which are projected from an upper surface of the substrate 110 are higher than surface levels of portions of the second anti-reflection layer 132 positioned on the first anti-reflection layer 131.

The back electrode 151 is positioned on substantially the entire back surface of the substrate 110.

The back electrode 151 contains a conductive material such as aluminum (Al) and is connected to the substrate 110. The back electrode 151 may include a plurality of portions or pieces.

The back electrode 151 collects charges (e.g., holes) moving to the substrate 110 and outputs the charges to an external device.

The back electrode 151, instead of aluminum (Al), may contain at least one selected from a group consisting of nickel (Ni), copper (Cu), silver (Ag), tin (Sn), zinc (Zn), indium (In), titanium (Ti), gold (Au), and a combination thereof, or other conductive materials different from the above.

The back surface field region 171 positioned into a portion of the substrate 110, and which is in contact with the back electrode 151 is a region (for example, a p⁺-type region) that is more heavily doped than the substrate 110 with impurities of the same conductive type as the substrate 110. Thereby, the back electrode 151 is electrically connected to the substrate 110 through the back surface field region 171.

A potential barrier is formed by a difference between impurity concentrations of a first conductive region of the substrate 110 and the back surface field region 171. Hence, the potential barrier prevents or reduces electrons from moving to the back surface field region 171 used as a moving path of holes and makes it easier for holes to move to the back surface field region 171. Thus, an amount of charges lost by a recombination and/or a disappearance of the electrons and the holes at and around the back surface of the substrate 110 is reduced, and a movement of charges to the back electrode 151 increases by accelerating a movement of desired charges (for example, holes). In addition, due to the higher impurity concentration of the back surface field region 171, contact resistance between the back surface field region 171 and the back electrode 151 is reduced, so that the charge transfer efficiency from the substrate 110 to the back electrode 151 is improved.

The solar cell 1 may further include a plurality of back bus bars positioned on the back surface of the substrate 110.

The plurality of back bus bars may be positioned directly on the back surface of the substrate 110 on which the back electrodes 151 are not positioned and be connected to adjacent portion of the back electrode 151, or be positioned on the back electrode 151 positioned on the back surface of the substrate 110 and be connected to the underlying back electrode 151. In this instance, the plurality of back bus bars are positioned opposite the plurality of front bus bars 142 with the substrate 110 therebetween.

The plurality of back bus bars collect charges from the back electrode 151 in the same manner as the plurality of front bus bars 142 and outputs the collected charges to the external device through a conductive tape, etc., for example, connected between the back bus bars and the external device.

The plurality of back bus bars may be formed of a material having better conductivity than the back electrodes 151. Further, the plurality of back bus bars may contain at least one conductive material, for example, silver (Ag).

An operation of the solar cell 1 having the above-described structure is described below.

When light irradiated to the solar cell 1 is incident on the emitter region 121 and the substrate 110 through the second and first anti-reflection layers 132 and 131, electrons and holes are generated in the emitter region 121 and the substrate 110 by light energy based on the incident light. In this instance, because a reflection loss of the light incident on the substrate 110 is reduced by the textured surface of the substrate 110 and the second and first anti-reflection layers 132 and 131, an amount of light incident on the substrate 110 further increases.

Due to the p-n junction of the substrate 110 and the emitter region 121, the electrons move to the n-type emitter region 121 and the holes move to the p-type substrate 110. The electrons moving to the n-type emitter region 121 are collected by the finger electrodes 141 and the front bus bars 142, and then move to the front bus bars 142. The holes moving to the p-type substrate 110 are collected by the back electrode 151. When the front bus bars 142 are connected to the back electrode 151 using electric wires, current flows therein to thereby enable use of the current for electric power.

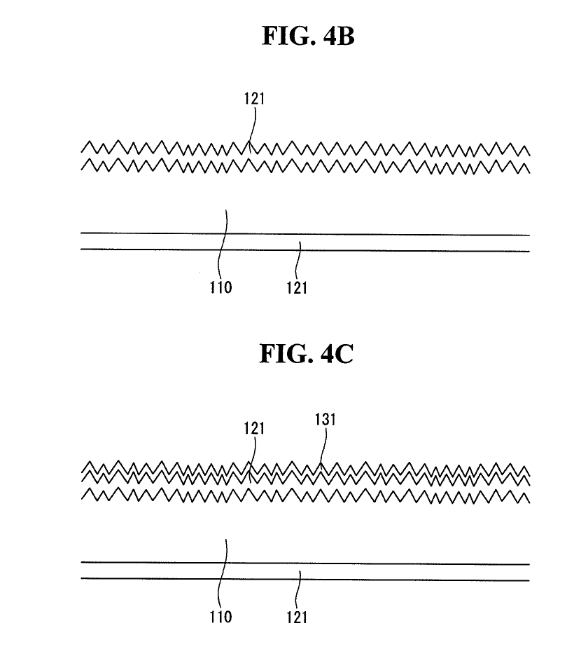

Next, the reflection prevention effect of the solar cell 1 having the first anti-reflection layer 131 on the emitter region 121, and the second anti-reflection layer 132 on the first anti-reflection layer 131 and the plurality of finger electrodes 141 is described with reference to FIG. 3.

FIG. 3 depicts a graph illustrating reflectivity according to variation of a wavelength of light according to an example embodiment of the present invention and a graph illustrating reflectivity according to variation of a wavelength of light according to a comparative example.

In FIG. 3, a graph (A) is a graph illustrating a change of reflectivity with respect a change of a wavelength of light in the solar cell according to the embodiment of the invention, and is measured in the solar cell having a first anti-reflection layer 131 and a second anti-reflection layer 132. In this instance, the first anti-reflection layer 131 is made of SiNx:H and has a refractive index of about 2.3 and a thickness of about 60 nm, and the second anti-reflection layer 132 is made of Al₂O₃ and has a refractive index of about 1.7 and a thickness of about 7 μm.

In FIG. 3, a graph (B) is a graph illustrating a change of reflectivity with respect a change of a wavelength of light in a solar cell according to a comparative example. As compared with the solar cell according to the embodiment of the invention, the solar cell of the comparative example has the same construction as the solar cell of the embodiment of the invention, except for the second anti-reflection layer. That is, unlike the solar cell of the embodiment of the invention, the second anti-reflection layer of the comparative example is positioned only on the first anti-reflection layer, and is made of silicon oxide (SiOx) with a refractive index of about 1.7. In the comparative example, the total thickness of the first and second anti-reflection layers is about 175 nm.

Referring to FIG. 3, in the graph (B) of the comparative example, an average weighted reflectivity over the entire wavelength band of light is about 2.8%. However, in the graph (A) of the embodiment of the invention, the average weighted reflectivity of light is about 3.1% that is similar to the average weighted reflectivity (about 2.8%) of the comparative example. Thereby, in a case (A) of the embodiment of the invention, the average weighted reflectivity does not largely increase by a function of the double-layered anti-reflection film, as compared with the solar cell of the comparative example, and the plurality of finger electrodes 141 are protected by the second anti-reflection layer. Accordingly, lifetime and performance of the solar cell 1 of the embodiment are increased or improved than the solar cell of the comparative example.

Also, as shown in FIG. 3, when a wavelength (i.e., a short wavelength) of light is one that is below about 700 nm, the reflectivity of light in the embodiment (A) is considerably reduced, as compared with the comparative example (B). Therefore, the first and second anti-reflection layers 131 and 132 according to the embodiment (A) is more effective for preventing or reducing reflection of light with the short wavelength (or a short wavelength range) than the light with a long wavelength (or a long wavelength range).

Usually, a distance that a minority carrier generated by the long wavelength absorbed in the substrate 110 (hereinafter, it is referred to as ‘a long wavelength minority carrier’) moves to the front electrode 140 (namely, bulk lifetime of minority carrier) is much longer than a distance that a minority carrier generated by the short wavelength (hereinafter, it is referred to as ‘a short wavelength minority carrier’) moves to the front electrode 140.

When the solar cell 1 is manufactured by using the substrate with a low purity level (e.g., a purity level less than 5 N) or a metallurgical grade silicon substrate, since the bulk lifetime of minority carriers (i.e., electrons) is very short, ranging approximately from 0.1 μs to 5 μs, a large amount of the long wavelength minority carriers is not transferred to the front electrode 140 normally and disappears during movement, while most of the short wavelength minority carriers are transferred to the front electrode 140 normally and are outputted. Here, the bulk lifetime may be a bulk lifetime of a substrate made of a bare silicon wafer.

When a solar cell is manufactured by using the substrate with the low purity level or the metallurgical grade silicon substrate, the improvement of an absorption efficiency of light with the short wavelength has more influence on the efficiency of the solar cell 1 rather than the improvement of an absorption efficiency of light with the long wavelength.

As shown in FIG. 3, when first and second anti-reflection layers 131 and 132 according to the embodiment of the present invention are used, the reflection prevention efficiency of light with the short wavelength is better than that of light with the long wavelength, and such an improvement is still more effective or pronounced for a solar cell that uses the substrate with the low purity level, or a metallurgical silicon substrate.

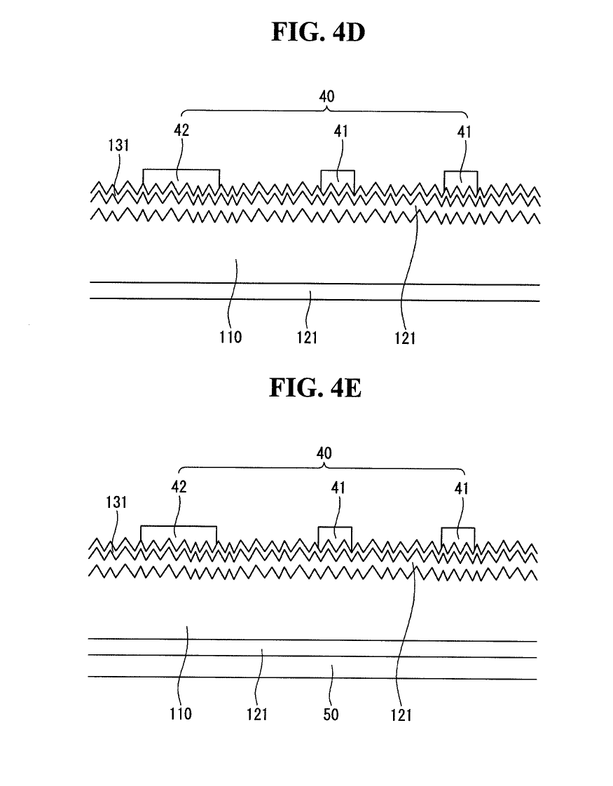

A method for manufacturing the solar cell 1 according to the embodiment of the invention is described below with reference to FIGS. 4A to 4F.

FIGS. 4A to 4F are sectional views sequentially showing processes for manufacturing a solar cell according to an example embodiment of the present invention.

As shown in FIG. 4A, an exposed surface, for example, a front (incident) surface of a substrate 110 of p-type polycrystalline is etched to form a textured surface (an uneven surface) having a plurality of jagged portions.

The textured surface may be formed using a dry etching method or a wet etching method. The substrate 110 may be of a p-type and may be formed of single crystal silicon. Further, a back surface as well as the front surface of the substrate 110 may etched to form the textured surface at the substrate 110. In the case, a portion of the back surface of the substrate 110 may be removed to remove the textured surface formed at the back surface of the substrate 110.

Next, as shown in FIG. 4B, a high temperature thermal process involving a material (for example, POCl₃ or H₃PO₄) containing a group V element impurity such as P, As, or Sb is performed on the substrate 110 to diffuse (or dope) the group V element impurity into the substrate 110, thus forming an emitter region 121 which contains the impurity of the group V element. Hence, the emitter region 121 is formed at the surface of the substrate 110 including a front surface, a rear surface, and a side surface. Unlike above embodiment of the invention, when the substrate 110 is of an n-type, a high temperature thermal process involving a material (for example, B₂H₆) containing a group DI element impurity is performed on the substrate 110, or the material containing the group DI element impurity is formed on the substrate 110 to form a p-type emitter region at the surface of the substrate 110. Next, phosphorous silicate glass (PSG) containing phosphor (P) or boron silicate glass (BSG) containing boron (B) produced when the p-type impurity or the n-type impurity is diffused into the substrate 110 is removed through an etching process using HF, etc. In addition, the impurity portion formed in the side surface of the substrate 110 by the diffusion of the impurity is removed by a laser beam or an etching.

Next, as shown in FIG. 4C a first anti-reflection layer 131 is formed on a portion of the emitter region 121 in the front surface of the substrate 110 using a plasma enhanced chemical vapor deposition (PECVD), etc. In this example, the first anti-reflection layer 131 may be made of hydrogenated silicon nitride (SiNx), etc., and may have a refractive index of about 2.1 to 2.4 and a thickness of about 30 m to 100 m. The first anti-reflection layer 131 may be formed on at least one portion of the sides of the substrate 110.

Next, referring to FIG. 4D, a front electrode paste is printed on corresponding portions of the first anti-reflection layer 131 using a screen printing method and then is dried at about 120° C. to 200° C. to form a front electrode pattern 40. The front electrode pattern 40 includes a first portion 41 for a plurality of finger electrodes and a second portion 42 for a plurality of front bus bars. The first and second portions 41 and 42 are extended in directions crossing to each other, and a width of the first portion 41 is less than that of the second portion 42.

In the example, the front electrode paste contains silver (Ag), glass frits containing lead (Pb), and so on. In an alternative example, the front electrode paste may contain another conductive materials instead of silver (Ag), and may not contain lead (Pb) or may contain lead (Pb) equal to or less than a predetermined amount (e.g., 1000 ppm).

Next, referring to FIG. 4E, a back electrode paste containing a conductive material such as aluminum (Al) is printed on the back surface of the substrate 110 using a screen printing method and then is dried at about 120° C. to 200° C. to form a back electrode pattern 50. The back electrode pattern 50 contains glass frits as well as the conductive material. However, the back electrode pattern 50 may not contain lead (Pb) or may contain lead (Pb) equal to or less than a predetermined amount (e.g., 1000 ppm).

A formation order of the front and back electrode patterns 40 and 50 may vary.

Next, as shown in FIG. 4F, the second anti-reflection layer 132 is applied or printed on the first anti-reflection layer 131 exposed and the first portion 41 of the front electrode pattern 40, and then a thermal process is performed, to form the second anti-reflection layer 132. In addition, during the thermal process, a front electrode 140 connected to the emitter region 121, a back electrode 151 contacted with the back surface of the substrate 110, and back surface field region 171 positioned into the back surface of the substrate 110 are formed. In the example embodiment of the invention, the second anti-reflection layer 132 may be formed on at least one portion of the sides of the substrate 110.

The thermal process may be performed at about 750° C. to 800° C.

In this instance, the anti-reflection layer 132 is formed of a material having a refractive index of about 1.6 to 2.0, for example, Al₂O₃. However, in another example, the second anti-reflection layer 132 may be formed or include other oxides other than Al₂O₃, non-oxide materials such as MgF, or polymer-based materials

The thickness of the second anti-reflection layer 132 may be changed by a reflection property of a material used therefor, for example, and may have the thickness of about 1 μm to several hundreds of micrometers.

The second anti-reflection layer 132 is formed using a printing method. The printing method may be an indirect printing method such as a screen printing method or a direct printing method to directly print on a desired portion without a mask. In addition, the printing method may be a spraying method or an ink-jet printing method. When the second anti-reflection layer 132 is formed by using the spraying method or the ink jet printing method, an ink or a material of a liquid state is printed on corresponding portions to print or apply the second anti-reflection layer 132. In this instance, for preventing or reducing the ink or the material being applied or printed on undesired portions, a mask or a side wall may be used.

By the thermal process, by an etching material such as lead (Pb) contained in the front electrode pattern 40, the front electrode pattern 40 penetrates through portions of the first anti-reflection layer 131 underlying the front electrode pattern 40 and is connected to the emitter region 121, thereby forming the front electrode 140. In this instance, the first portion 41 of the front electrode pattern 40 is formed as the plurality of finger electrodes 141 of the front electrode 140, and the second portion 42 of the front electrode pattern 40 is formed as the plurality of front bus bars 142 of the front electrode 140.

In addition, during the thermal process, the back electrode pattern 50 is formed as a back electrode 151 in contact with the substrate 110, and aluminum (Al) contained in the back electrode pattern 50 is diffused (or doped) over the emitter region 121 formed at the back surface of the substrate 110 to form an impurity region, that is, the back surface field region 171 that is highly doped with an impurity of the same conductive type as the substrate 110. In this instance, an impurity doped concentration of the back surface field region 171 is higher than that of the substrate 110. Thereby, the back surface field region 171 is mainly formed into a portion of the back surface of the substrate 110, on which the back electrode pattern 50 is applied.

Moreover, in performing the thermal process, metal components contained in the patterns 40 and 50 are chemically coupled to the contacted emitter region 121 and the substrate 110, respectively, such that a contact resistance is reduced and thereby a transmission efficiency of the charges is improved to improve a current flow.

Next, an edge isolation is carried out by using laser beams or an etching process to remove the emitter region 121 formed in the sides of the substrate 110. Thereby, the emitter region 121 formed in the front surface of the substrate 110 and the emitter region 121 formed in the back surface of the substrate 110 are separated electrically, thereby completing the solar cell 1 (see FIGS. 1 and 2). The timing of the edge isolation process may be changed, if necessary or desired.

In the solar cell 1 of the double-layered anti-reflection film having the first and second anti-reflection layers 131 and 132, the front electrode pattern 40 for the front electrode 140 is positioned not entirely on the second anti-reflection layer 132 but also on the first anti-reflection layer 131. Thus, the layer number of the anti-reflection film underlying the front electrode pattern 40 is reduced from two layers to one layer, and thereby a thickness of the anti-reflection film existing under the front electrode pattern 40 is too reduced, such that the thickness of the film to be penetrated by the front electrode pattern 40 in the thermal process is decreased. Thereby, the time for manufacturing the front electrode 140 and the back electrode 151 is reduced and the processes for manufacturing the front electrode 140 and the back electrode 151 are simplified. Further, a contact resistance between the front electrode 140 and the emitter region 121 underlying the front electrode 140 is reduced, such that the charge transfer efficiency is improved.

In addition, since the second anti-reflection layer 132 is positioned on the plurality of finger electrodes 142 on which the conductive tape is not attached and exposed, corrosion or characteristic charge of the finger electrodes 141 due to moisture or impurities from the outside is prevented or decreased.

However, in general, a polymer-based material is weak in heat. Thereby, when the polymer-based material is subjected to a high temperature, the material is deteriorated to cause change of the characteristics of the material.

Thereby, when the second anti-reflection layer 132 is made of a material (e.g., the polymer-based material) that is weak in heat, by an alternative method different from the method described above, the front electrode 140 and the back electrode 151 are formed using the thermal process at a high temperature (e.g., about 750° C. to 800° C.), and then the second anti-reflection layer 132 is formed.

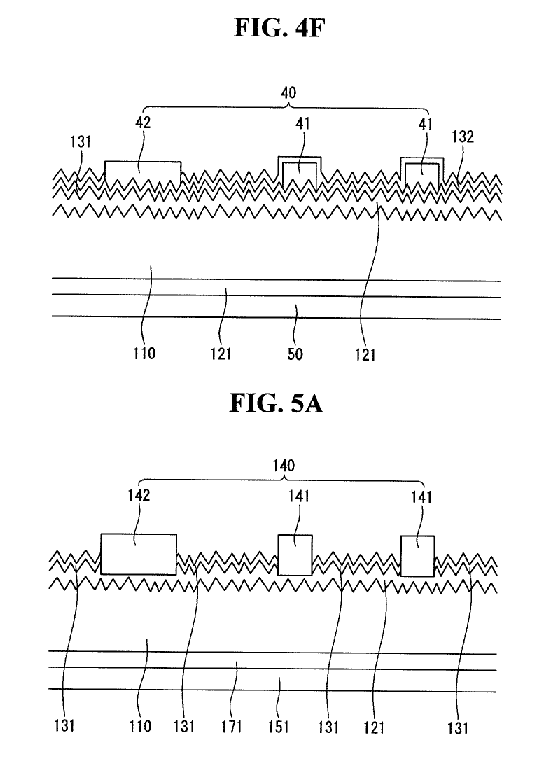

The alternative method is described with reference to FIGS. 5A and 5B as well as 4A to 4E. The description of the alternative method that overlaps with the method of FIGS. 4A to 4E is omitted.

As already described referring to FIGS. 4A to 4E, the emitter region 121 is formed into the substrate 110, the first anti-reflection layer 131 is formed, and then the front electrode pattern 40 and the back electrode pattern 50 are printed on desired portions and dried.

Next, as shown in FIG. 5A, a thermal process is performed to the substrate 110 with the patterns 40 and 50 at a high temperature (e.g., about 750° C. to 800° C.). Thereby, the front electrode pattern 40 penetrates through portions of the first anti-reflection layer 131 underlying the front electrode pattern 40 and is in contact with the emitter region 121, to form a front electrode 140 having a plurality of finger electrodes 141 and a plurality of front bus bars 142. The back electrode pattern 50 is contacted with the substrate 110 to form a back electrode 151 connected to the substrate 110. In the thermal process, impurities such as aluminum (Al) contained in the back electrode pattern 50 are injected into a back surface of the substrate 110 to form a back surface field region 171 into a portion of the substrate 110, which is in contact with the back electrode 151.

Next, as shown in FIG. 5B, a second anti-reflection layer 132 is applied on portions of the first anti-reflection layer 131, on which the front electrode 140 is not positioned, and the plurality of finger electrodes 141 and then a thermal process is performed. Thereby, the second anti-reflection layer 132 substantially exposing the plurality of front bus bars 142 is formed, and then the edge isolation process is formed to complete the solar cell 1 (see FIGS. 1 and 2).

Since the thermal process is performed for drying or hardening the second anti-reflection layer 132 at about 100° C. to 300° C. less than the temperature (e.g., about 750° C. to 800° C.) for the formation of the front electrode 140, the deterioration or the characteristic change of the second anti-reflection layer 132 made of the polymer-based material due to the high temperature is prevented or reduced, and thereby, the efficiency decrease of the solar cell 1 is prevented or reduced.

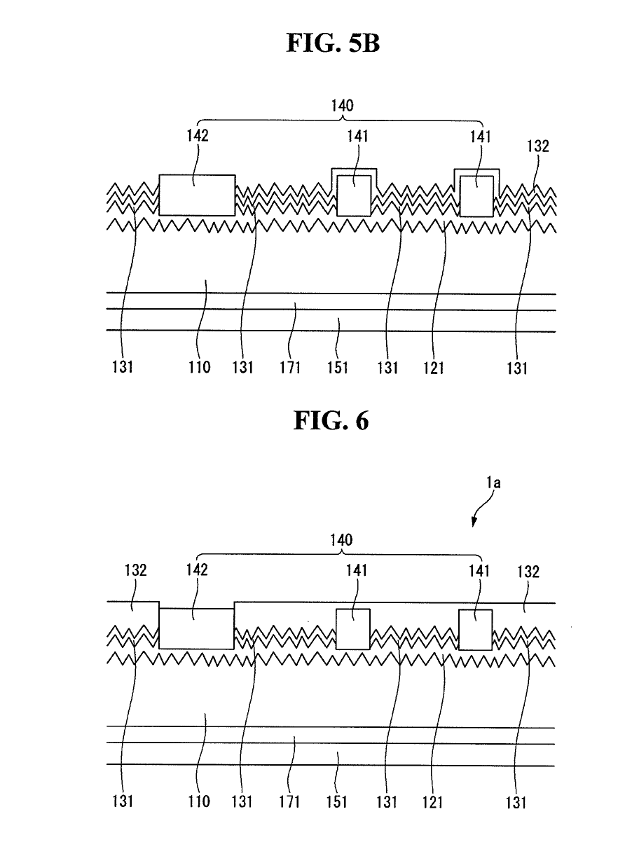

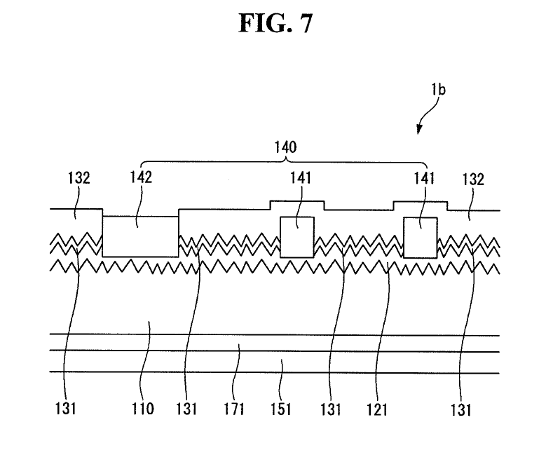

Referring to FIGS. 6 and 7, solar cells 1a and 1b according to another embodiment of the present invention are described. FIGS. 6 and 7 are partial perspective views of solar cells according to another example embodiment of the invention respectively.

A structure of the solar cells 1a and 1b of the embodiment is the same as that shown in FIGS. 1 and 2, except for a positional relationship between a surface level (a level of an upper surface) of a second anti-reflection layer 132 and a surface level (a level of an upper surface) of a front electrode 140. Thereby the detailed description of the same structure as the solar cell 1 of FIGS. 1 and 2 is omitted.

That is, unlike FIGS. 1 and 2, the surface level of the second anti-reflection layer 132 is higher than that of the front electrode 140, including that of each finger electrode 141 or each front bus bar 142.

In the solar cell 1a of FIG. 6, the surface level of the second anti-reflection layer 132 is substantially the same level regardless of the position of the second anti-reflection layer 132. That is, the surface levels of portions of the second anti-reflection layer 132, which are positioned on the first anti-reflection layer 131 and the surface levels of portions of the second anti-reflection layer 132, which are positioned on the plurality of finger electrodes 141 are equal to each other.

However, in the solar cell 1b of FIG. 7, the surface level of the second anti-reflection layer 132 is changed in accordance with the position of the second anti-reflection layer 132. Since a surface level of each finger electrode 141 is higher than that of the first anti-reflection layer 131, the surface levels of portions of the second anti-reflection layer 132, which are positioned on the first anti-reflection layer 131 are lower than the surface levels of portions of the second anti-reflection layer 132, which are positioned on the plurality of finger electrodes 141. In the embodiments of FIGS. 6 and 7, the surface level of the front bus bars 142 may be lower than the surface level of immediately adjacent portions of the second anti-reflection layer 132.

In FIG. 6, a difference between the surface level of the front bus bar 142 and the surface level of the second anti-reflection layer 132 may be the same as a thickness of the second anti-reflection layer 132 that is positioned on the finger electrode 141. In FIG. 7, a difference between the surface level of the front bus bar 142 and the surface level of the second anti-reflection layer 132 may be about half of the thickness of the second anti-reflection layer 132 that is positioned on the finger electrode 141, but can also be other values.

For the solar cells 1a and 1b of FIGS. 6 and 7, when the surface level of the second anti-reflection layer 132 is higher than that of each front bus bar 142, it is easy to attach a conductive tape such as a ribbon to the plurality of front bus bars 142. That is, when an adhesive is applied on the front bus bars 142 for easily attaching the conductive tape, the second anti-reflection layer 132 functions as a side wall, and thereby the attachment of the adhesive becomes easy and waste of the adhesive is prevented.

In embodiments of the invention such as FIGS. 6 and 7, a portion of the second anti-reflection layer 132 that is immediately adjacent to the front bus bar 142 is shown having a perpendicular edge. In other embodiments of the invention, such an edge may be inclined or rounded. In other embodiments of the invention, a portion of the second anti-reflection layer 132 may be formed over portions of the front bus bar 142.

A method for manufacturing the solar cells la and lb is the same as the method shown in FIGS. 4A to 4F or 5A and 5B. However, a desired thickness of the second anti-reflection layer 132 may be obtained by adjusting the printing number of the second anti-reflection layer 132 and an amount of a material printed for the second anti-reflection layer 132.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

What is claimed is:

1. A solar cell comprising:
a substrate of a first conductive type;
an emitter region of a second conductive type opposite to the first conductive type and forming a p-n junction with the substrate;
a first anti-reflection layer positioned on the emitter region;
a first electrode connected to the emitter region;
a second anti-reflection layer positioned on the first anti-reflection layer and the first electrode; and
a second electrode connected to the substrate.

2. The solar cell of claim 1, further comprising a bus bar connected to the emitter region and the first electrode.

3. The solar cell of claim 2, wherein the second anti-reflection layer is not positioned on the bus bar.

4. The solar cell of claim 2, wherein a level of an upper surface of the second anti-reflection layer positioned on the first anti-reflection layer is lower than a level of an upper surface of the bus bar.

5. The solar cell of claim 2, wherein a level of an upper surface of the second anti-reflection layer positioned on the first anti-reflection layer is higher than a level of an upper surface of the bus bar.

6. The solar cell of claim 5, wherein the second anti-reflection layer comprises a first portion positioned on the first anti-reflection layer and a second portion positioned on the first electrode, and levels of upper surfaces of the first and second portion are substantially equal to each other.

7. The solar cell of claim 5, wherein the second anti-reflection layer comprises a first portion positioned on the first anti-reflection layer and a second portion positioned on the first electrode, and levels of upper surfaces of the first and second portion are different from each other.

8. The solar cell of claim 7, wherein the level of the upper surface of the first portion of the second anti-reflection layer is lower than the level of the upper surface of the second portion of the second anti-reflection layer.

9. The solar cell of claim 2, wherein the first anti-reflection layer is positioned only on portions of the emitter regions, on which the first electrode and the bus bar are not positioned, so that the first and second anti-reflection layers are positioned on the emitter region as a double-layered structure and the second anti-reflection layer is positioned on the first electrode as a single-layered structure.

10. The solar cell of claim 1, wherein a refractive index of the first anti-reflection layer is greater than a refractive index of the second anti-reflection layer.

11. The solar cell of claim 10, wherein the refractive index of the first anti-reflection layer is about 2.1 to 2.4 and the refractive index of the second anti-reflection layer is about 1.6 to 2.0.

12. The solar cell of claim 1, wherein the first and second anti-reflection layers are made of a same material.

13. The solar cell of claim 12, wherein the first and second anti-reflection layers are made of silicon oxide or silicon nitride.

14. The solar cell of claim 1, wherein the first and second anti-reflection layers are made of a different material from each other.

15. The solar cell of claim 14, wherein the second anti-reflection layer is made of at least one of an oxide, a non-oxide, and a polymer-based material.

16. The solar cell of claim 14, wherein the first and second anti-reflection layers are made of silicon oxide or silicon nitride.

17. The solar cell of claim 1, wherein the second anti-reflection layer has a thickness of about 1 μm to 600 μm.

18. The solar cell of claim 17, wherein the first anti-reflection layer has a thickness less than a thickness of the second anti-reflection layer.

19. The solar cell of claim 1, wherein the first anti-reflection layer has a thickness of about 30 nm to 100 nm.

20. The solar cell of claim 1, further comprising a field region connected to the second electrode.

21. The solar cell of claim 1, wherein the substrate is a polycrystalline silicon substrate of a purity level of 5 N or less.

22. The solar cell of claim 1, wherein the substrate is a polycrystalline silicon substrate of a purity level of 2 N to 5 N.

23. The solar cell of claim 1, wherein the substrate is a metallurgical grade silicon substrate.

24. The solar cell of claim 1, wherein the substrate comprises aluminum (Al) in an amount of 0.01 ppmw to 0.8 ppmw.

25. The solar cell of claim 24, wherein the substrate comprises iron (Fe) in an amount of 0.01 ppmw to 0.8 ppmw.

26. A method for manufacturing a solar cell, the method comprising:
forming an emitter region on a front surface of the substrate to form a p-n junction with the substrate;
forming a first anti-reflection layer on the emitter region;
locally forming a front electrode pattern on the first anti-reflection layer;
forming a back electrode pattern on a back surface of the substrate;
forming a second anti-reflection layer on the first anti-reflection layer and the front electrode pattern; and
forming a front electrode using the front electrode pattern that penetrates through the first anti-reflection layer and connects to the emitter region, and a back electrode using the back electrode pattern that connects to the substrate.

27. The method of claim 26, wherein the front electrode pattern comprises a first portion and a second portion, and the front electrode comprises a finger electrode and a bus bar connected to the finger electrode, and the first portion forms the finger electrode and the second forms the bus bar.

28. The method of claim 27, wherein the second anti-reflection layer is positioned on the first portion, so that the second anti-reflection layer is positioned not on the bus bar but on the finger electrode.

29. A method for manufacturing a solar cell, the method comprising:
forming an emitter region on a front surface of the substrate to form a p-n junction with the substrate;
forming a first anti-reflection layer on the emitter region;
locally forming a front electrode pattern on the first anti-reflection layer;
forming a back electrode pattern on a back surface of the substrate;
forming a front electrode using the front electrode pattern that penetrates through the first anti-reflection layer and connects to the emitter region, and a back electrode using the back electrode pattern that connects to the substrate; and
forming a second anti-reflection layer on the first anti-reflection layer and a portion of the front electrode.

30. The method of claim 29, wherein the front electrode comprises a finger electrode and a bus bar connected to the finger electrode.

31. The method of claim 30, wherein the portion of the front electrode on which the second anti-reflection layer is formed is the finger electrode.

32. The method of claim 29, wherein the first anti-reflection layer is formed by a plasma enhanced chemical vapor deposition method.

33. The method of claim 29, wherein the second anti-reflection layer is formed by a printing method.
